(19) United States
(12) Patent Application Publication
(10) Pub. No.: US 2025/0203765 A1
(43) Pub. Date: Jun. 19, 2025

(54) STRETCHABLE DEVICE

(71) Applicant: Murata Manufacturing Co., Ltd., Nagaokakyo-shi (JP)

(72) Inventors: Yui NAKAMURA, Nagaokakyo-shi (JP); Toshifumi ASUKAI, Nagaokakyo-shi (JP)

(21) Appl. No.: 19/066,516

(22) Filed: Feb. 28, 2025

Related U.S. Application Data
(63) Continuation of application No. PCT/JP2023/032845, filed on Sep. 8, 2023.

(30) Foreign Application Priority Data
Sep. 28, 2022 (JP) 2022-155135

(51) Int. Cl. H05K 1/02; H05K 1/14

(52) U.S. Cl. CPC H05K 1/0283; H05K 1/142; H05K 2201/058; H05K 2201/0753; H05K 2201/09236

(57) ABSTRACT

A stretchable device that includes: a first substrate having stretchability; a first wiring on a first main surface of the first substrate; a second substrate facing the first substrate in a first direction that is a thickness direction of the first substrate and connected to the first substrate; a second wiring on a first main surface of the second substrate, facing the first wiring in the first direction, and electrically connected to the first wiring; and a first protective layer on the first main surface of the first substrate so as to cover a part of the first wiring, wherein the first substrate and the first protective layer overlap each other in a first overlapping region, the first wiring and the second wiring are electrically connected in a wiring region, and the first overlapping region is separated from the wiring region when viewed from the first direction.

### CROSS REFERENCE TO RELATED APPLICATIONS

The present application is a continuation of International application No. PCT/JP2023/032845, filed Sep. 8, 2023, which claims priority to Japanese Patent Application No. 2022-155135, filed Sep. 28, 2022, the entire contents of each of which are incorporated herein by reference.

### TECHNICAL FIELD

The present disclosure relates to a stretchable device.

### BACKGROUND ART

A conventional stretchable device is one described in Japanese Patent Application Laid-Open No. 2008-108890 (Patent Document 1). This stretchable device includes a first substrate, a first wiring provided on the first substrate, a second substrate facing the first substrate in a thickness direction of the first substrate, a second wiring provided on the second substrate and facing the first wiring in a thickness direction, and a connection member electrically connecting the first wiring and the second wiring. When viewed from the thickness direction, a region where the first wiring and the second wiring overlap and a region where the connection member exists constitute a wiring region where the first wiring and the second wiring are electrically connected. When viewed from the thickness direction, the wiring region coincides with a substrate overlapping region where the first substrate and the second substrate overlap.

### SUMMARY OF THE DISCLOSURE

In the conventional stretchable device, in a case where the wiring is exposed to the outside and a water droplet or a foreign substance is attached across adjacent wirings, a short circuit may occur between the adjacent wirings, and the stretchable device may be damaged. Further, when a metal wiring comes into contact with air or moisture, oxidation or corrosion of the wiring may occur. In view of the above, it is conceivable to cover a surface of the wiring with a protective layer. Specifically, the protective layer is provided in all portions exposed from the second substrate in the first wiring. That is, when viewed from the thickness direction, a wiring region where the first wiring and the second wiring are electrically connected and a protective layer overlapping region where the first substrate and the protective layer overlap each other are adjacent to each other.

However, it has been found that when the stretchable device expands and contracts, there is a possibility that damage to the stretchable device such as breakage of the first wiring may occur between the wiring region and the protective layer overlapping region when viewed from the thickness direction, and there is a possibility that performance of the stretchable device may be lowered such as increase in a resistance value of the first wiring.

Therefore, an object of the present disclosure is to provide a stretchable device capable of reducing damage to the stretchable device and suppressing lowering in performance of the stretchable device when the stretchable device expands and contracts.

In order to solve the above problem, a stretchable device according to one aspect of the present disclosure includes: a first substrate having stretchability; a first wiring on a first main surface of the first substrate; a second substrate facing the first substrate in a first direction that is a thickness direction of the first substrate and connected to the first substrate; a second wiring on a first main surface of the second substrate, facing the first wiring in the first direction, and electrically connected to the first wiring; and a first protective layer on the first main surface of the first substrate so as to cover a part of the first wiring, wherein the first substrate and the first protective layer overlap each other in a first overlapping region, the first wiring and the second wiring are electrically connected in a wiring region, and the first overlapping region is separated from the wiring region when viewed from the first direction.

According to the stretchable device according to one aspect of the present disclosure, it is possible to reduce damage to the stretchable device and to suppress lowering in performance of the stretchable device when the stretchable device expands and contracts.

### BRIEF EXPLANATION OF THE DRAWINGS

FIG. 1 is a partial enlarged top view schematically illustrating a stretchable device according to a first embodiment of the present disclosure.

FIG. 2 is an exploded plan view schematically illustrating the stretchable device according to the first embodiment of the present disclosure.

FIG. 3 is a sectional view taken along III-III of FIG. 1.

FIG. 4 is a partial sectional view of the stretchable device according to a second embodiment of the present disclosure.

FIG. 5 is a partial sectional view of the stretchable device according to a third embodiment of the present disclosure.

FIG. 6 is a partial sectional view of the stretchable device according to a fourth embodiment of the present disclosure.

FIG. 7 is a partial sectional view of the stretchable device according to a fifth embodiment of the present disclosure.

FIG. 8 is a partial sectional view of the stretchable device according to a sixth embodiment of the present disclosure.

FIG. 9 is a partial sectional view of the stretchable device according to a seventh embodiment of the present disclosure.

FIG. 10 is a partial sectional view of the stretchable device according to an eighth embodiment of the present disclosure.

### DESCRIPTION OF THE PREFERRED EMBODIMENTS

Hereinafter, an embodiment of the present disclosure will be described in detail with reference to the drawings. In each embodiment, a difference from description before the embodiment will be mainly described. Particularly, similar functions and effects achieved by similar configurations will not be mentioned sequentially for each of the embodiments. Among constituent elements in the embodiments below, a constituent element not described in an independent claim will be described as an optional constituent element. Further, sizes and size-ratios of constituent elements illustrated in the drawings are not necessarily precise. Further, in the drawings, substantially the same configurations are denoted by the same reference symbols, and redundant description may be omitted or simplified.

### First Embodiment

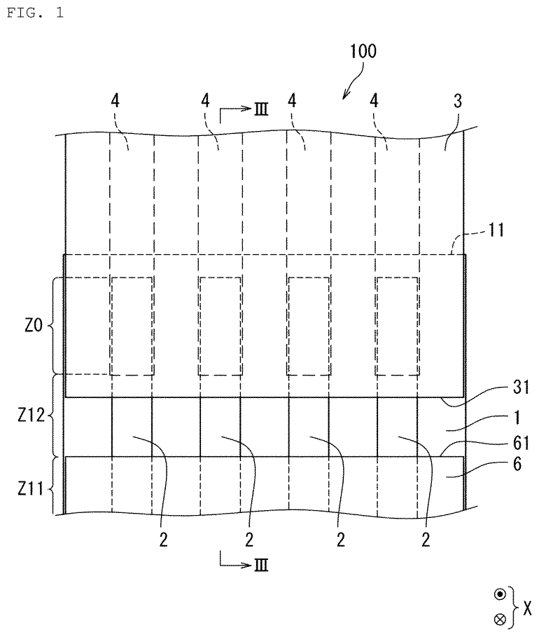

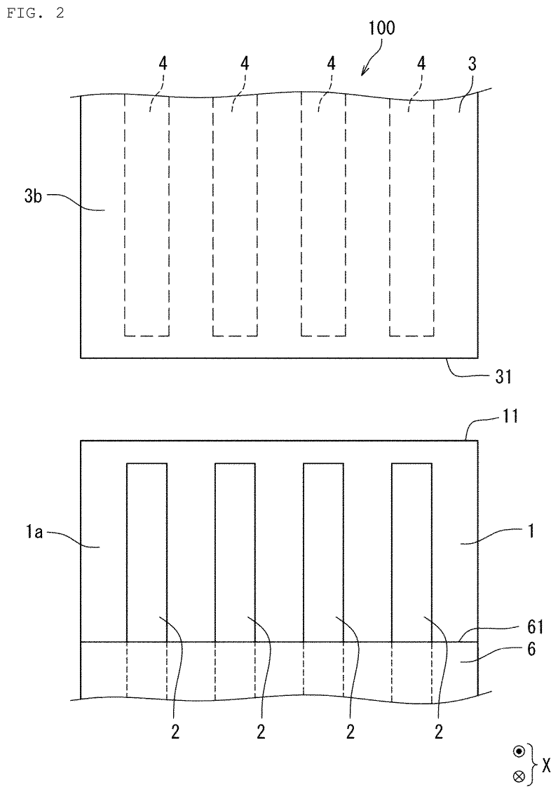

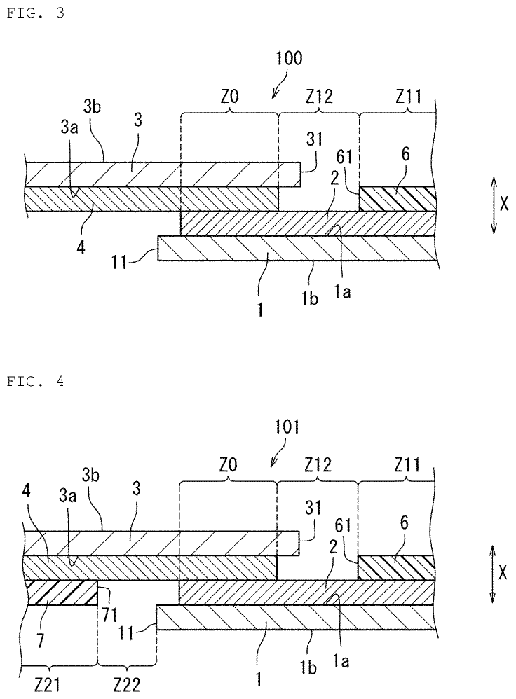

A structure of a stretchable device 100 according to a first embodiment will be described with reference to FIGS. 1, 2, and 3. FIG. 1 is a partial top view of the stretchable device 100. FIG. 2 is an exploded plan view of the stretchable device 100. FIG. 3 is a sectional view of the stretchable device 100 taken along line III-III in FIG. 1. Note that a sectional view in the present description is a sectional view that is parallel to a first direction and includes a region where a first substrate 1 and a second substrate 3 overlap as viewed from the first direction that is a thickness direction of the first substrate. The first direction is indicated by a double-headed arrow X. A thickness direction of the first substrate 1, a thickness direction of the second substrate 3, and a first direction X coincide with each other.

The stretchable device 100 includes the first substrate 1, the second substrate 3, a first wiring 2, a second wiring 4, and a first protective layer 6. The first substrate 1 and the second substrate 3 are connected. The first wiring 2 provided on a first main surface 1a of the first substrate 1 and the second wiring 4 provided on a first main surface 3a of the second substrate 3 are electrically connected. The first protective layer 6 is provided on the first main surface 1a of the first substrate 1 so as to cover a part of the first wiring 2.

Note that a shape of the stretchable device 100 is not particularly limited. In the present description, a structure in which two substrates are connected is described as an example, but three or more substrates may be connected. Further, the first wiring 2 is not limited to arrangement as illustrated in FIG. 1, and an extending direction is also not limited. Specifically, a longitudinal direction of the first substrate 1 and an extending direction of the first wiring 2 do not need to coincide with each other, and the first substrate 1 and the first wiring 2 do not need to extend in one direction. Further, the number of the first wirings 2 is not particularly limited, and may be one or more. In a case where there are a plurality of the first wirings 2, the first wirings 2 may include a wiring not electrically connected to the second wiring 4. The same applies to arrangement and the number of the second wirings 4.

Further, the term “on” in the present description does not need to coincide with the upper and lower sides when the stretchable device 100 is used. More specifically, “on a main surface of the first substrate 1” indicates not an absolute direction such as a vertical upward direction defined in the direction of gravity, but a direction toward the outside between the outside and the inside with the main surface of the first substrate 1 as a boundary, with the main surface as a reference. The same applies to “on a main surface of the second substrate 3”. Further, “above” with respect to a certain element includes not only an upper position away from the element, that is, an upper position with another object interposed between them on the element or an upper position at an interval, but also a position in contact with and immediately above (on) the element.

Hereinafter, these constituent elements and arrangement of these will be described below. As illustrated in FIGS. 1, 2, and 3, the first substrate 1 and the second substrate 3 face each other in the first direction X, and partly overlap each other as viewed from the first direction X. Similarly, the first wiring 2 and the second wiring 4 face each other in the first direction X.

The first substrate 1 has stretchability. Since the first substrate 1 is stretchable, it is possible to reduce the risk of breakage due to expansion and contraction at the time of use of the stretchable device 100 without suppressing expansion and contraction of the first wiring 2.

Examples of stretchable substrates include sheet-shaped or film-shaped substrates made from a stretchable resin material. The resin material preferably contains, for example, at least one type of resin selected from a group including acryl-based resin, styrene-based resin, and urethane-based resin. Examples of the urethane-based resin include thermoplastic polyurethane. Thickness of the first substrate 1 is not particularly limited, but is preferably 1 mm or less, more preferably 100 μm or less, still more preferably 50 μm or less from the viewpoint of preventing expansion and contraction of a surface of a living body from being impaired when the first substrate 1 is attached to the living body. Further, thickness of the first substrate 1 is preferably 1 μm or more.

The first substrate 1 has the first main surface 1a and a second main surface 1b located opposite to each other. The first substrate 1 has a first substrate end portion 11 that connects the first main surface 1a and the second main surface 1b. The first substrate end portion 11 is an end portion closer to the second substrate 3 in the first substrate 1, in other words, an end portion overlapping the second wiring 4 as viewed from the first direction X. Specifically, the first substrate end portion 11 is an end portion closer to the second substrate 3 between both end portions in an up-down direction in FIG. 1, and is an end portion closer to the second substrate 3 between both end portions in a left-right direction in FIG. 3. Note that, in FIGS. 1, 2, and 3, an end portion different from the first substrate end portion 11 is not illustrated.

The first wiring 2 is provided on the first main surface 1a of the first substrate 1. The first wiring 2 preferably has stretchability. Examples of a material of the first wiring 2 include a mixture of metal powder such as Ag, Cu, and/or Ni as conductive particles and elastomer-based resin such as silicone resin. An average particle size of the conductive particles is not particularly limited, but is preferably 0.01 μm to 10 μm. Further, a shape of the conductive particles is preferably spherical, and is not limited to spherical, and may be a flat shape for improving stretchability or a structure having a protrusion. Further, the elastomer-based resin contains at least one type of resin (elastomer-based resin) selected from a group including epoxy-based resin, urethane-based resin, acryl-based resin, and silicone-based resin, and is preferable in securing stretchability.

Thickness of the first wiring 2 is preferably 100 μm or less, and more preferably 50 μm or less. Further, thickness of the stretchable wiring is more preferably 1 μm or more. Further, thickness, width, and length of the first wiring are not particularly limited. Note that the first wiring 2 does not need to have stretchability.

A method of forming the first wiring 2 on the first substrate 1 will be described. In a case where a material of the first wiring 2 is, for example, conductive paste containing a mixture of Ag and resin, the conductive paste is applied to the first substrate 1. A method of application may be screen printing, gravure printing, or inkjet printing. After the above, the conductive paste is thermally cured so as to obtain a predetermined resistance value, so as to form the first wiring 2 on the first substrate 1.

The second substrate 3 preferably has stretchability. The second substrate 3 preferably has Young's modulus larger than that of the first wiring 2. Specifically, a substrate such as a flexible printed circuit (FPC), a flexible flat cable (FFC), or a printed circuit board (PCB) is exemplified. By making Young's modulus larger than that of the first wiring 2, pressure is easily applied to a bonding portion at the time of pressure bonding, and bonding can be performed with low pressure. That is, by using low pressure, damage to the substrate at the time of bonding can be reduced. Further, the second substrate 3 preferably has Young's modulus larger than that of the first substrate 1. Since resistance to an impact at the time of connection is improved, connection reliability can be further improved.

The second substrate 3 has a first main surface 3a and a second main surface 3b located opposite to each other. The second substrate 3 has a second substrate end portion 31 connecting the first main surface 3a and the second main surface 3b. The second substrate end portion 31 is an end portion closer to the first substrate 1 of the second substrate 3, in other words, an end portion overlapping the first wiring 2 when viewed from the first direction X. Specifically, the second substrate end portion 31 is an end portion closer to the first substrate 1 between both end portions in the up-down direction in FIG. 1, and is an end portion closer to the first substrate 1 between both end portions in the left-right direction in FIG. 3. Note that, in FIGS. 1, 2, and 3, an end portion different from the second substrate end portion 31 is not illustrated.

The second substrate 3 is connected to the first substrate 1. That is, the first main surface 1a of the first substrate 1 and the first main surface 3a of the second substrate 3 are directly connected by welding or the like. Specifically, the first main surface 1a of the first substrate 1 and the first main surface 3a of the second substrate 3 are thermocompression-bonded. Note that the first substrate 1 and the second substrate 3 may be connected to each other by an adhesive member such as a thermoplastic adhesive.

Note that the second substrate 3 does not need to have stretchability. Examples of a material of the second substrate 3 include sheet-like or film-like substrates such as PET and polyimide, and substrates such as FPC, FFC, and PCB. Further, a material of the second substrate 3 may be the same as a material of the first substrate 1.

The second wiring 4 is provided on the first main surface 3a of the second substrate 3. The second wiring 4 preferably has stretchability. The second wiring 4 is a wiring preferably having Young's modulus larger than that of the first wiring 2. For example, a metal wiring such as copper foil is exemplified. Thickness of the second wiring 4 is preferably 1 μm to 100 μm, and more preferably 50 μm or less. The first wiring 2 and the second wiring 4 are electrically connected in direct contact with each other. Note that the second wiring 4 does not need to have stretchability. Further, a material of the second wiring 4 may be the same as a material of the first wiring 2.

The second wiring 4 is electrically connected to the first wiring 2. Specifically, the first wiring 2 and the second wiring 4 are electrically connected in contact with each other. When viewed from the first direction X, a region where the first wiring 2 and the second wiring 4 overlap constitutes a wiring region 20 where the first wiring 2 and the second wiring 4 are electrically connected.

The first wiring 2 and the second wiring 4 may be electrically connected via a conductive connection member. At this time, when viewed from the first direction X, a region where the first wiring 2 and the second wiring 4 overlap and a region where the connection member exists constitute the wiring region 20 where the first wiring 2 and the second wiring 4 are electrically connected.

The first protective layer 6 is provided on the first main surface 1a of the first substrate 1 so as to cover a part of the first wiring 2. As described above, since the first protective layer 6 covers a part of the first wiring 2, a short circuit between adjacent ones of the first wirings 2 can be suppressed if a water droplet or a foreign substance adheres across the adjacent ones of the first wirings 2, and contact of the first wiring 2 with air or moisture is reduced so that occurrence of oxidation or corrosion of the first wiring 2 can be suppressed. Note that the first protective layer 6 may be provided so as to integrally cover all the first wirings 2, or the first protective layer 6 may be provided separately so as to individually cover each of the first wirings 2.

Specifically, the first protective layer 6 covers a part of the first wiring 2, is in contact with the first main surface 1a of the first substrate 1, and overlaps the first substrate 1 when viewed from the first direction X. Preferably, the first protective layer 6 is in contact with a part of a region exposed from the first wiring 2 in the first substrate 1. Note that the first protective layer 6 may cover the first wiring 2 and may not be in contact with the first substrate 1.

Specifically, the first protective layer 6 is preferably a resin material or a mixture of a resin material and an inorganic material as an example, and examples of the resin material include elastomer-based resin such as urethane-based, styrene-based, olefin-based, silicone-based, fluorine-based, nitrile rubber, latex rubber, vinyl chloride, ester-based, and amide-based resin, epoxy, phenol, acrylic, polyester, imide-based, rosin, cellulose, polyethylene terephthalate-based, polyethylene naphthalate-based, and polycarbonate-based resin. Further, the first protective layer 6 preferably has insulating property. Since the first protective layer 6 has insulating property, ion migration in the first wiring 6 can be more reliably suppressed. The first protective layer 6 is provided by, for example, applying an insulating material or bonding a laminate material.

Thickness of the first protective layer 6 is preferably 1 μm to 100 μm, and more preferably 50 μm or less. By setting thickness of the first protective layer 6 to 1 μm or more, durability of the first protective layer 6 can be secured. Further, by setting thickness of the first protective layer 6 to 100 μm or less, overall height can be reduced. Note that, in a case where thickness of the first protective layer 6 is not constant, a maximum dimension in the first direction X of the first protective layer 6 is defined as the thickness.

Further, the first protective layer 6 has a first protective layer end portion 61. The first protective layer end portion 61 is an end portion closer to the first substrate end portion 11 in the first protective layer 6, specifically, an end portion closer to the first substrate end portion 11 between both end portions in the up-down direction in FIG. 1, and is an end portion closer to the first substrate end portion 11 between both end portions in the left-right direction in FIG. 3. Note that, in FIGS. 1, 2, and 3, an end portion different from the first protective layer end portion 61 is not illustrated.

When viewed from the first direction X, a first overlapping region Z11 where the first substrate 1 and the first protective layer 6 overlap is separated from the wiring region Z0 where the first wiring 2 and the second wiring 4 are electrically connected. Specifically, when viewed from the first direction X, the first protective layer end portion 61 and an end portion of the second wiring 4 are separated from each other. When viewed from the first direction X, the wiring region Z0 and the first overlapping region Z11 are separated in an extending direction of the first wiring 2. In the present embodiment, an extending direction of the first wiring 2 and an extending direction of the second wiring 4 coincide with each other.

According to the above configuration, since the first overlapping region Z11 is separated from the wiring region Z0 when viewed from the first direction X, a first non-overlapping region Z12 that does not overlap the first protective layer 6 of the first substrate 1 exists between the first overlapping region Z11 and the wiring region zo when viewed from the first direction X. That is, when viewed from the first direction X, the first non-overlapping region Z12 exists between the first protective layer end portion 61 and an end portion of the second wiring 4.

By the above, when the stretchable device 100 is expanded and contracted, stress applied to the stretchable device 100 can be alleviated in the first non-overlapping region Z12. Therefore, damage to the stretchable device 100 such as breakage of the first wiring 2 can be reduced, and lowering in performance of the stretchable device 100 such as an increase in a resistance value of the first wiring 2 can be suppressed.

In short, in the wiring region Z0, since the first wiring 2, the second wiring 4, the first substrate 1, and the second substrate 3 overlap each other, stretchable performance of the first substrate 1 is lowered, and the region is a portion having high rigidity in the stretchable device 100. Further, in the first overlapping region Z11, since the first substrate 1, the first wiring 2, and the first protective layer 6 overlap with each other, stretchable performance of the first substrate 1 is lowered, and the region is a portion having high rigidity in the stretchable device 100. On the other hand, in the first non-overlapping region Z12, since the first substrate 1 is not covered with the first protective layer 6, stretchable performance of the first substrate 1 can be secured, and the region is a portion having stretchability in the stretchable device 100. For this reason, when the stretchable device 100 expands and contracts, stress applied to a portion having large rigidity can be absorbed by the first non-overlapping region Z12.

That is, the inventors of the present application have focused on the fact that stress locally concentrates on a portion having high rigidity when the stretchable device 100 is expanded or contracted. Furthermore, the inventors of the present application have focused on the fact that rigidity of the wiring region 20 is different from rigidity of the first overlapping region Z11 because the number of stacked layers (four layers of the first wiring 2, the second wiring 4, the first substrate 1, and the second substrate 3) in the wiring region Z0 is different from the number of stacked layers (three layers of the first substrate 1, the first wiring 2, and the first protective layer 6) in the first overlapping region Z11. Then, the inventors of the present application have found that stress concentrates between the wiring region Z0 and the first overlapping region Z11 in a case where the wiring region Z0 and the first overlapping region Z11 are adjacent as viewed from the first direction X as in the conventional technique. From such a viewpoint, the inventors of the present application have realized the stretchable device 100 capable of alleviating stress by forming a portion where the stress concentrates (that is, a portion between the wiring region Z0 and the first overlapping region Z11) as a stretchable portion (that is, the first non-overlapping region Z12).

Preferably, a shortest distance between the first overlapping region Z11 and the wiring region 20 when viewed from the first direction X is 1 μm to 30 mm, and more preferably 1 μm to 10 mm. That is, a shortest distance between the first protective layer end portion 61 and the second substrate end portion 31 in an extending direction of the first wiring 2 as viewed from the first direction X is 1 μm to 30 mm. Therefore, since the shortest distance is 1 μm or more, stretchable performance of the first substrate 1 can be improved in the first non-overlapping region Z12, and stress alleviation can be improved in the first non-overlapping region Z12. Further, since a shortest distance is 30 mm or less, stretchable performance of the first substrate 1 can be sufficiently secured in the first non-overlapping region Z12, and exposure of the first wiring 2 can be reduced to reduce a short circuit between adjacent ones of the first wirings 2.

Next, connection of the stretchable device 100 will be described. In a case where the first substrate 1 and the second substrate 3 are connected, the first substrate 1 and the second substrate 3 are heated and pressurized so as to be thermocompression-bonded. By the above, the first substrate 1 and the second substrate 3 are connected. A method of pressure-bonding the first substrate 1 and the second substrate 3 is not particularly limited. Further, the first wiring 2 is in contact with and electrically connected to the second wiring 4.

### Second Embodiment

Next, a second embodiment will be described with reference to FIG. 4. FIG. 4 is a partial sectional view of a stretchable device 101 according to the second embodiment. The stretchable device 101 according to the second embodiment is different from the stretchable device 100 according to the first embodiment in that a second protective layer is provided.

As illustrated in FIG. 4, the stretchable device 101 of the second embodiment further includes a second protective layer 7. A material and thickness of the second protective layer 7 are the same as a material and thickness of the first protective layer 6, but the thicknesses may be different from each other, and similarly, the materials may be different from each other.

The second protective layer 7 is provided on the first main surface 3a of the second substrate 3 so as to cover a part of the second wiring 4. As described above, since the second protective layer 7 covers a part of the second wiring 4, a short circuit between adjacent ones of the second wirings 4 can be suppressed if a water droplet or a foreign substance adheres across the adjacent ones of the second wirings 4, and contact of the second wiring 4 with air or moisture is reduced so that occurrence of oxidation or corrosion of the second wiring 4 can be suppressed.

Specifically, the second protective layer 7 covers a part of the second wiring 4, is in contact with the first main surface 3a of the second substrate 3, and overlaps the second substrate 3 when viewed from the first direction X. Preferably, the second protective layer 7 is in contact with a part of a region exposed from the second wiring 4 in the second substrate 3. Note that the second protective layer 7 may cover the second wiring 4 and does not need to be in contact with the second substrate 3.

The second protective layer 7 has a second protective layer end portion 71. The second protective layer end portion 71 is an end portion closer to the second substrate end portion 31 in the second protective layer 7, specifically, an end portion closer to the second substrate end portion 31 between both end portions in the left-right direction in FIG. 4. Note that in FIG. 4, an end portion different from the second protective layer end portion 71 is not illustrated.

When viewed from the first direction X, a second overlapping region Z21 where the second substrate 3 and the second protective layer 7 overlap is separated from the wiring region Z0. Specifically, the second protective layer end portion 71 and the first substrate end portion 11 are separated from each other when viewed from the first direction X. When viewed from the first direction X, the wiring region Z0 and the second overlapping region Z21 are separated in an extending direction of the second wiring 4. In the present embodiment, an extending direction of the first wiring 2 and an extending direction of the second wiring 4 coincide with each other.

According to the above configuration, since the second overlapping region Z21 is separated from the wiring region Z0 when viewed from the first direction X, a second non-overlapping region Z22 that does not overlap the second protective layer 7 of the second substrate 3 exists between the second overlapping region Z21 and the wiring region Z0 when viewed from the first direction X. That is, when viewed from the first direction X, the second non-overlapping region Z22 exists between the second protective layer end portion 71 and the first substrate end portion 11.

By the above, when the stretchable device 101 is expanded and contracted, stress applied to the stretchable device 101 can be alleviated in the second non-overlapping region Z22. In particular, in a case where the second substrate 3 has stretchability, damage to the stretchable device 101 such as breakage of the second wiring 4 can be reduced, and lowering in performance of the stretchable device 101 such as increase in a resistance value of the second wiring 4 can be suppressed.

### Third Embodiment

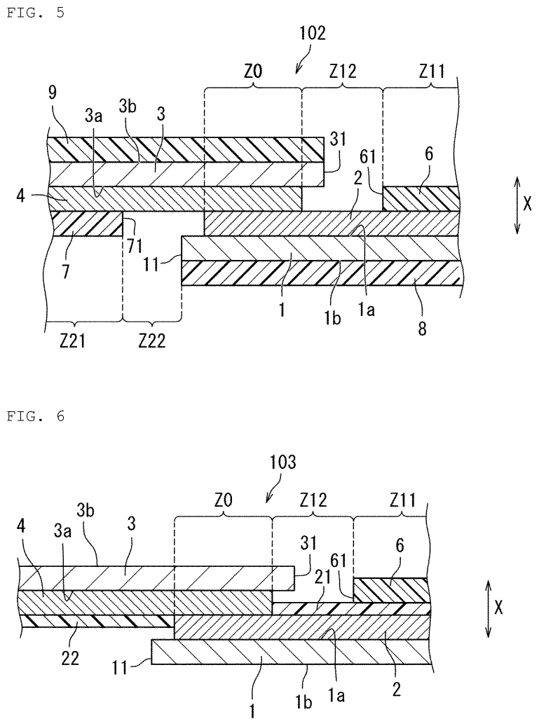

Next, a third embodiment will be described with reference to FIG. 5. FIG. 5 is a partial sectional view of a stretchable device 102 according to the third embodiment. The stretchable device 102 according to the third embodiment is different from the stretchable device 101 according to the second embodiment in that a third protective layer and a fourth protective layer are provided.

As illustrated in FIG. 5, the stretchable device 102 of the third embodiment further includes a third protective layer 8 and a fourth protective layer 9. A materials and thickness of the third protective layer 8 and the fourth protective layer 9 are the same as a materials and thickness of the first protective layer 6, but the thicknesses may be different from each other, and similarly, the materials may be different from each other.

The third protective layer 8 is provided on the second main surface 1b of the first substrate 1. The third protective layer 8 preferably covers the entire surface of the second main surface 1b of the first substrate 1, but only needs to cover at least a part of the second main surface 1b of the first substrate 1. According to the above configuration, waterproof performance of the first substrate 1 is improved by the third protective layer 8. Further, biocompatibility is improved by using a biocompatible material for the third protective layer 8.

The fourth protective layer 9 is provided on the second main surface 3b of the second substrate 3. The fourth protective layer 9 preferably covers the entire surface of the second main surface 3b of the second substrate 3, but may cover a part of the second main surface 3b of the second substrate 3. According to the above configuration, waterproof performance of the second substrate 3 is improved by the fourth protective layer 9. Further, biocompatibility is improved by using a biocompatible material for the fourth protective layer 9.

Note that only one of the third protective layer 8 and the fourth protective layer 9 may be provided. Further, at least one of the third protective layer 8 and the fourth protective layer 9 may be provided in the stretchable device 100 according to the first embodiment.

### Fourth Embodiment

Next, a fourth embodiment will be described with reference to FIG. 6. FIG. 6 is a partial sectional view of a stretchable device 103 according to the fourth embodiment. The stretchable device 103 according to the fourth embodiment is different from the stretchable device 100 according to the first embodiment in that a first insulating layer and a second insulating layer are provided.

As illustrated in FIG. 6, the stretchable device 103 of the fourth embodiment further includes a first insulating layer 21 and a second insulating layer 22. A material of the first insulating layer 21 and the second insulating layer 22 is different from a material of the first protective layer 6.

As the first insulating layer 21 and the second insulating layer 22, one having a water absorption rate lower than that of the first substrate 1 is preferable. Examples of a material of the first insulating layer 21 and the second insulating layer 22 include silicone-based resin, acryl-based resin, olefin-based resin, modified urethane-based resin, vinyl chloride-based resin, polyester-based resin, polyamide-based resin, polyolefin-based resin, polyethylene-based resin, and polypropylene-based resin materials. The first insulating layer 21 and the second insulating layer 22 are formed by, for example, printing.

The first insulating layer 21 covers at least a part of an exposed surface of the first wiring 2. An exposed surface of the first wiring 2 is a surface exposed to the outside of an outer surface of the first wiring 2. Specifically, an exposed surface of the first wiring 2 is a surface that is not covered with the first substrate 1, the first protective layer 6, and the second wiring 4 in the first wiring 2. The first insulating layer 21 preferably covers the entire exposed surface of the first wiring 2, but may cover a part of the exposed surface of the first wiring 2. Further, the first insulating layer 21 also preferably exists between the first wiring 2 and the first protective layer 6. Further, although the first insulating layer 21 does not overlap the second wiring 4 in the first direction X, a part of the first insulating layer 21 may overlap the second wiring 4 in the first direction X. According to the above configuration, the first insulating layer 21 prevents a short circuit between adjacent ones of the first wirings 2 due to a water droplet or a foreign matter, and reliability is improved.

Here, a method for forming the first insulating layer 21 will be described. Insulating paste as a material of the first insulating layer 21 is printed on the first wiring 2 using a screen printing method or the like. At this time, in a section orthogonal to an extending direction of the first wiring 2, the insulating paste is preferably printed larger than width of the first wiring 2 by 1 μm to 10 mm, and more preferably by 20 μm to 1000 μm.

The second insulating layer 22 covers at least a part of an exposed surface of the second wiring 4. The exposed surface of the second wiring 4 is a surface exposed to the outside of an outer surface of the second wiring 4. Specifically, an exposed surface of the second wiring 4 is a surface that is not covered with the second substrate 3 and the first wiring 2 in the second wiring 4. The second insulating layer 22 preferably covers the entire exposed surface of the second wiring 4, but may cover a part of the exposed surface of the second wiring 4. Further, although the second insulating layer 22 does not overlap the first wiring 2 in the first direction X, a part of the second insulating layer 22 may overlap the first wiring 2 in the first direction X. According to the above configuration, the second insulating layer 22 prevents a short circuit between adjacent ones of the second wirings 4 due to a water droplet or a foreign matter, and reliability is improved.

Note that only one of the first insulating layer 21 and the second insulating layer 22 may be provided. Further, at least one of the first insulating layer 21 and the second insulating layer 22 may be provided in the stretchable devices 101 and 102 according to the second and third embodiments.

### Fifth Embodiment

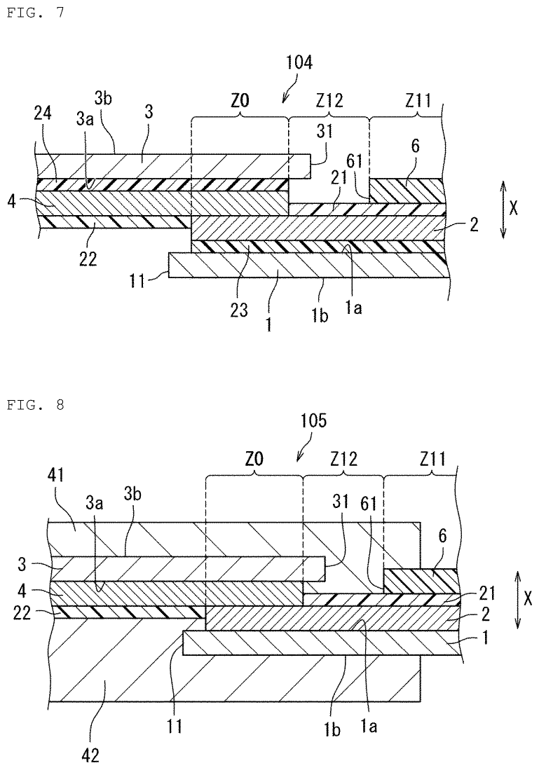

Next, a fifth embodiment will be described with reference to FIG. 7. FIG. 7 is a partial sectional view of a stretchable device 104 according to the fifth embodiment. The stretchable device 104 according to the fifth embodiment is different from the stretchable device 103 according to the fourth embodiment in that a third insulating layer and a fourth insulating layer are provided.

As illustrated in FIG. 7, the stretchable device 104 of the fifth embodiment further includes a third insulating layer 23 and a fourth insulating layer 24. A material of the third insulating layer 23 and the fourth insulating layer 24 may be the same as or different from a material of the first insulating layer 21 and the second insulating layer 22.

The third insulating layer 23 is arranged between the first wiring 2 and the first substrate 1 in the first direction X. In other words, the third insulating layer 23 is provided on the first main surface 1a of the first substrate 1 and is in contact with a lower surface (that is, a surface of the first wiring 2 facing the first main surface 1a of the first substrate 1) of the first wiring 2.

In a case where the first substrate 1 has moisture permeability, moisture may enter the first wiring 2 from the first substrate 1, and ion migration may occur. By providing the third insulating layer 23, entry of moisture from the first substrate 1 to the first wiring 2 can be suppressed. That is, the stretchable device 104 in which a short circuit of the first wiring 2 is suppressed is provided.

The fourth insulating layer 24 is arranged between the second wiring 4 and the second substrate 3 in the first direction X. In other words, the fourth insulating layer 24 is provided on the first main surface 3a of the second substrate 3 and is in contact with a lower surface (that is, a surface of the second wiring 4 facing the first main surface 3a of the second substrate 3) of the second wiring 4.

In a case where the second substrate 3 has moisture permeability, moisture may enter the second wiring 4 from the second substrate 3, and ion migration may occur. By providing the fourth insulating layer 24, entry of moisture from the second substrate 3 to the second wiring 4 can be suppressed. That is, the stretchable device 104 in which a short circuit of the second wiring 4 is suppressed is provided.

Note that only one of the third insulating layer 23 and the fourth insulating layer 24 may be provided. Further, at least one of the third insulating layer 23 and the fourth insulating layer 24 may be provided in the stretchable devices 100, 101, and 102 according to the first, second, and third embodiments.

Further, for example, the third insulating layer 23 may be arranged so as to cover only a lower surface of the first wiring 2, or may be arranged at a portion where the first wiring 2 of the first substrate 1 is not present. Further, the third insulating layer 23 may be arranged so as to cover the entire first substrate 1. Further, the third insulating layer 23 only needs to be in contact with the second wiring 2, and a different layer may be arranged between the first substrate 1 and the third insulating layer 23. The fourth insulating layer 24 may be similar to the third insulating layer 23.

### Sixth Embodiment

Next, a sixth embodiment will be described with reference to FIG. 8. FIG. 8 is a partial sectional view of a stretchable device 105 according to the sixth embodiment. The stretchable device 105 according to the sixth embodiment is different from the stretchable device 103 according to the fourth embodiment in that a first coating layer and a second coating layer are provided.

As illustrated in FIG. 8, the stretchable device 105 of the sixth embodiment further includes a first coating layer 41 and a second coating layer 42. A material of the first coating layer 41 and the second coating layer 42 is different from a material of the first protective layer 6.

The first coating layer 41 covers at least an end portion on the first substrate side of the second substrate 3. With such a structure, the second substrate 3 can be protected from external force. More preferably, the first coating layer 41 covers the first main surface 1a side of the first substrate 1. Specifically, the first coating layer 41 covers at least a part of the first main surface 1a of the first substrate 1, at least a part of the first insulating layer 21, at least a part of the first protective layer 6, and at least a part of the second main surface 3b of the second substrate 3. With such a configuration, a portion exposed from the first protective layer 6 in the first wiring 2 and the first protective layer 6 can be protected from external force.

Examples of the first coating layer 41 include a resin material. For example, the first coating layer 41 is preferably resin having flexibility. Specifically, the first coating layer 41 is formed of ionomer-based resin, polyester-based resin, styrene-based resin, olefin-based resin, epoxy-based resin, urethane-based resin, acryl-based resin, or silicone-based resin, and is preferably formed of silicone-based resin. Further, the first coating layer 41 may be thermoplastic resin. Specific examples of the thermoplastic polyurethane (TPU) or the styrene-based resin include styrene-butadiene-styrene copolymer resin (SBS). Note that the first coating layer 41 may be formed of a plurality of members. By using resin for the first coating layer 41, a connection portion can be more suitably protected from external force.

The second coating layer 42 covers at least an end portion on the second substrate side of the first substrate 1. With such a structure, the first substrate 1 can be protected from external force. More preferably, the second coating layer 42 covers the first main surface 3a side of the second substrate 3. Specifically, the second coating layer 42 covers at least a part of the first main surface 3a of the second substrate 3, at least a part of the second insulating layer 22, and at least a part of the second main surface 1b of the first substrate 1. With the above configuration, a portion exposed from the second insulating layer 22 of the second wiring 4 and the second insulating layer 22 can be protected from external force.

Examples of the second coating layer 42 include a resin material. For example, the first coating layer 41 is preferably resin having flexibility. Specifically, the first coating layer 41 is formed of ionomer-based resin, polyester-based resin, styrene-based resin, olefin-based resin, epoxy-based resin, urethane-based resin, acryl-based resin, or silicone-based resin, and is preferably formed of silicone-based resin. Further, the second coating layer 42 may be a thermoplastic resin. Specific examples of the thermoplastic polyurethane (TPU) or the styrene-based resin include styrene-butadiene-styrene copolymer resin (SBS). Note that the second coating layer 42 may be formed of a plurality of members. By using resin for the second coating layer 42, a connection portion can be more suitably protected from external force. Further, the first coating layer 41 and the second coating layer 42 may be the same member or different members.

A member containing resin such as the first protective layer 6, the first insulating layer 21, and the second insulating layer 22 may have cytotoxicity. By providing the first coating layer 41, leakage of a component having cytotoxicity can be suppressed. The same applies to an effect of the second coating layer 42. Further, by providing the first coating layer 41 and the second coating layer 42, it is possible to suppress leakage of a component having higher cytotoxicity.

Further, the first coating layer 41 continuously covers the second main surface 3b of the second substrate 3, the first insulating layer 21, and the first protective layer 6. In other words, the first coating layer 41 continuously covers the wiring region 20, the first non-overlapping region Z12, and the first overlapping region Z11. By the above, since the first coating layer 41 covers the first non-overlapping region Z12 constituting a recessed portion with respect to the wiring region Z0 and the first overlapping region Z11, it is possible to provide the stretchable device 105 where a recess portion can be reduced. Therefore, it is possible to provide the stretchable device 105 with improved wearability.

Further, the first coating layer 41 overlaps the first protective layer 6 when viewed from the first direction X. By the above, since the first coating layer 41 is arranged on the first protective layer 6, a step between the first main surface 1a side of the first substrate 1 and the second main surface 3b side of the second substrate 3 is reduced by thickness of the first protective layer 6.

Further, the second coating layer 42 continuously covers the first main surface 3a side of the second substrate 3 and the second main surface 1b side of the first substrate 1. This makes it possible to prevent damage on the first main surface 3a side of the second substrate 3 and the second main surface 1b side of the first substrate 1.

Note that only one of the first coating layer 41 and the second coating layer 42 may be provided. Further, at least one of the first coating layer 41 and the second coating layer 42 may be provided in the stretchable devices 100, 101, 102, and 104 according to the first, second, third, and fifth embodiments.

### Seventh Embodiment

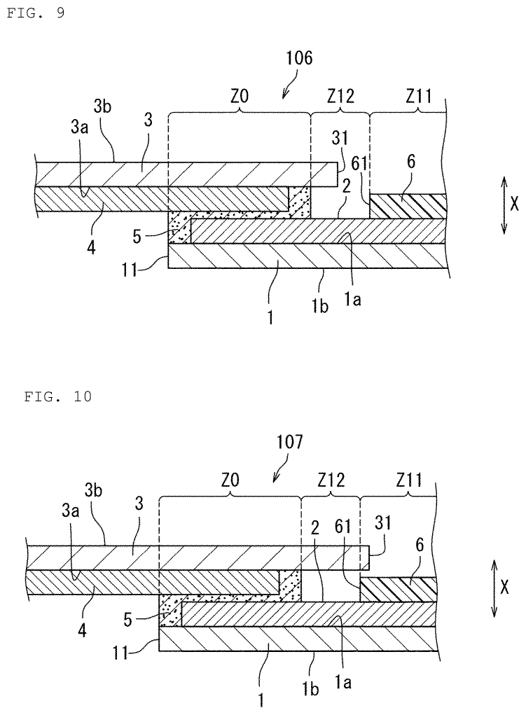

Next, a seventh embodiment will be described with reference to FIG. 9. FIG. 9 is a partial sectional view of a stretchable device 106 according to the seventh embodiment. The stretchable device 106 according to the seventh embodiment is different from the stretchable device 100 according to the first embodiment in that a connection member is provided.

As illustrated in FIG. 9, the stretchable device 106 of the seventh embodiment further includes a connection member 5. In FIG. 9, the connection member 5 is indicated by dot hatching for convenience. As described above, the connection member 5 electrically connects the first wiring 2 and the second wiring 4. At this time, when viewed from the first direction X, a region where the first wiring 2 and the second wiring 4 overlap and a region where the connection member 5 exists constitute the wiring region Z0 where the first wiring 2 and the second wiring 4 are electrically connected.

A part of the connection member 5 is located between the first wiring 2 and the second wiring 4. Further, a part of the connection member 5 is located outside an end portion of the first wiring 2 so as to cover an end portion in an extending direction of the first wiring 2. Further, a part of the connection member 5 is located outside an end portion of the second wiring 4 so as to cover an end portion in an extending direction of the second wiring 4. Examples of the connection member 5 include an anisotropic conductive film (ACF), conductive paste, and solder. The connection member 5 preferably contains resin and conductive particles. When the conductive particles contained in the connection member 5 come into contact with the first wiring 2 and the second wiring 4, the first wiring 2 and the second wiring 4 are electrically connected.

Furthermore, the connection member 5 connects the first wiring 2 and the second wiring 4. Further, the connection member 5 is in contact with the first main surface 1a of the first substrate 1 and the first main surface 3a of the second substrate 3 to connect the first substrate 1 and the second substrate 3.

Next, connection of the stretchable device 106 will be described. When the first substrate 1 and the second substrate 3 are connected, the first substrate 1 and the second substrate 3 may be subjected to pressure bonding such as pressurization. By performing such processing, the connection member 5 is deformed, and the entire thickness changes. That is, height of the stretchable device 106 can be reduced. Further, in a case where the connection member 5 containing conductive particles is provided between the first wiring 2 and the second wiring 4 as described above, conduction cannot be achieved if a distance between the first wiring 2 and the second wiring 4 in the first direction X is larger than a maximum diameter of the conductive particles. In such a case, a distance between the first wiring 2 and the second wiring 4 in the first direction X is reduced by performing the above-described pressure bonding. Therefore, the first wiring 2 and the second wiring 4 can be electrically connected more reliably.

Note that in a case where the first wiring 2 and the second wiring 4 are electrically connected before pressure bonding, pressure bonding may not be performed. Further, in a case where the connection member 5 has adhesiveness, pressure bonding may not be performed. Further, a pressure bonding method is not particularly limited.

### Eighth Embodiment

Next, an eighth embodiment will be described with reference to FIG. 10. FIG. 10 is a partial sectional view of a stretchable device 107 according to the eighth embodiment. The stretchable device 107 according to the eighth embodiment is different from the stretchable device 106 according to the seventh embodiment in length of the second substrate.

As illustrated in FIG. 10, in the stretchable device 107 of the eighth embodiment, the second substrate 3 extends to a position overlapping the first protective layer 6 in the first direction X. Specifically, the second substrate end portion 31 of the second substrate 3 overlaps the first protective layer 6 when viewed from a direction orthogonal to the first direction X. That is, the second substrate 3 overlaps the first non-overlapping region Z12. By the above, the second substrate 3 can protect an exposed portion of the first wiring 2 located in the first non-overlapping region Z12.

Note that the present disclosure is not limited to the above-described embodiments, and can be changed in design without departing from the gist of the present disclosure. For example, features of the first to eighth embodiments may be combined in a various manner.

The present disclosure includes an aspect below.
<1> A stretchable device including: a first substrate having stretchability; a first wiring on a first main surface of the first substrate; a second substrate facing the first substrate in a first direction that is a thickness direction of the first substrate and connected to the first substrate; a second wiring on a first main surface of the second substrate, facing the first wiring in the first direction, and electrically connected to the first wiring; and a first protective layer on the first main surface of the first substrate so as to cover a part of the first wiring, wherein the first substrate and the first protective layer overlap each other in a first overlapping region, the first wiring and the second wiring are electrically connected in a wiring region, and the first overlapping region is separated from the wiring region when viewed from the first direction.
<2> The stretchable device according to <1>, further including a second protective layer on the first main surface of the second substrate, in which the second substrate and the second protective layer overlap each other in a second overlapping region, and the second overlapping region is separated from the wiring region when viewed from the first direction.
<3> The stretchable device according to <1> or <2>, further including a third protective layer on a second main surface of the first substrate.
<4> The stretchable device according to any one of <1> to <3>, further including a fourth protective layer on a second main surface of the second substrate.
<5> The stretchable device according to any one of <1> to <4>, further including a first insulating layer that covers at least a part of an exposed surface of the first wiring.
<6> The stretchable device according to any one of <1> to <5>, further including a second insulating layer that covers at least a part of an exposed surface of the second wiring.
<7> The stretchable device according to any one of <1> to <6>, further including a third insulating layer between the first wiring and the first substrate.
<8> The stretchable device according to any one of <1> to <7>, further including a fourth insulating layer between the second wiring and the second substrate.
<9> The stretchable device according to any one of <1> to <8>, further including a first coating layer that covers a first main surface side of the first substrate.
<10> The stretchable device according to <9>, in which the first coating layer overlaps the first protective layer when viewed from the first direction.
<11> The stretchable device according to any one of <1> to <10>, further including a second coating layer that covers a first main surface side of the second substrate.
<12> The stretchable device according to <11>, in which the second coating layer continuously covers the first main surface side of the second substrate and a second main surface side of the first substrate.

### DESCRIPTION OF REFERENCE SYMBOLS

100, 101, 102, 103, 104, 105, 106, 107: Stretchable device
1: First substrate
1a: First main surface
1b: Second main surface
11: First substrate end portion
2: First wiring
3: Second substrate
3a: First main surface
3b: Second main surface
31: Second substrate end portion
4: Second wiring
5: Connection member
6: First protective layer
61: First protective layer end portion
7: Second protective layer
71: Second protective layer end portion
8: Third protective layer
9: Fourth protective layer
21: First insulating layer
22: Second insulating layer
23: Third insulating layer
24: Fourth insulating layer
41: First coating layer
42: Second coating layer
X: First direction
Z0: Wiring region
Z11: First overlapping region
Z12: First non-overlapping region
Z21: Second overlapping region
Z22: Second non-overlapping region

1. A stretchable device comprising:
a first substrate having stretchability;
a first wiring on a first main surface of the first substrate;
a second substrate that faces the first substrate in a first direction that is a thickness direction of the first substrate and is connected to the first substrate;
a second wiring on a first main surface of the second substrate, facing the first wiring in the first direction, and electrically connected to the first wiring; and
a first protective layer on the first main surface of the first substrate so as to cover a part of the first wiring, wherein
the first substrate and the first protective layer overlap each other in a first overlapping region, the first wiring and the second wiring are electrically connected in a wiring region, and the first overlapping region is separated from the wiring region when viewed from the first direction.

2. The stretchable device according to claim 1, further comprising a second protective layer on the first main surface of the second substrate, wherein
the second substrate and the second protective layer overlap each other in a second overlapping region, and the second overlapping region is separated from the wiring region when viewed from the first direction.

3. The stretchable device according to claim 1, further comprising a third protective layer on a second main surface of the first substrate.

4. The stretchable device according to claim 3, further comprising a fourth protective layer on a second main surface of the second substrate.

5. The stretchable device according to claim 1, further comprising a fourth protective layer on a second main surface of the second substrate.

6. The stretchable device according to claim 1, further comprising a first insulating layer that covers at least a part of an exposed surface of the first wiring.

7. The stretchable device according to claim 6, further comprising a second insulating layer that covers at least a part of an exposed surface of the second wiring.

8. The stretchable device according to claim 1, further comprising a second insulating layer that covers at least a part of an exposed surface of the second wiring.

9. The stretchable device according to claim 1, further comprising a third insulating layer between the first wiring and the first substrate.

10. The stretchable device according to claim 9, further comprising a fourth insulating layer between the second wiring and the second substrate.

11. The stretchable device according to claim 1, further comprising a fourth insulating layer between the second wiring and the second substrate.

12. The stretchable device according to claim 1, further comprising a first coating layer that covers a first main surface side of the first substrate.

13. The stretchable device according to claim 9, wherein the first coating layer overlaps the first protective layer when viewed from the first direction.

14. The stretchable device according to claim 12, further comprising a second coating layer that covers a first main surface side of the second substrate.

15. The stretchable device according to claim 14, wherein the second coating layer continuously covers the first main surface side of the second substrate and a second main surface side of the first substrate.

16. The stretchable device according to claim 2, further comprising:
a third protective layer on a second main surface of the first substrate; and
a fourth protective layer on a second main surface of the second substrate.

17. The stretchable device according to claim 7, further comprising:
a third insulating layer between the first wiring and the first substrate; and
a fourth insulating layer between the second wiring and the second substrate.

18. The stretchable device according to claim 7, further comprising:
a first coating layer that covers a first main surface side of the first substrate; and
a second coating layer that covers a first main surface side of the second substrate.

19. The stretchable device according to claim 1, wherein an end portion of the second substrate overlaps the first protective layer when viewed from a direction orthogonal to the first direction.

20. The stretchable device according to claim 1, a shortest distance between the first overlapping region and the wiring region when viewed from the first direction is 1 μm to 30 mm.
